(19) United States
(12) Patent Application Publication
(10) Pub. No.: US 2008/0041613 A1
(43) Pub. Date: Feb. 21, 2008

(54) Operation device

(75) Inventor: Yukio Hiramoto, Saitama (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 11/882,793

(22) Filed: Aug. 6, 2007

(30) Foreign Application Priority Data
Aug. 16, 2006 (JP) 2006-222035

(51) Int. Cl. H05K 5/00

(52) U.S. Cl. 174/17 CT

(57) ABSTRACT

An operation device includes a front panel having an opening for operation, an elastically deformable operation component having an operation button and being attached to the front panel so as to cover the opening in the front panel in watertight condition, an insertion part provided in substantially a central portion of the operation component, a retaining ring attached to the insertion part in watertight condition and having a through-hole in a central portion thereof, and an operation shaft having a knob attached thereto and extending through the through-hole in watertight condition. The operation button of the operation component and the operation shaft operate respective operable parts arranged inside the front panel.

### CROSS REFERENCES TO RELATED APPLICATIONS

The present invention contains subject matter related to Japanese Patent Application JP 2006-222035 filed in the Japanese Patent Office on Aug. 16, 2006, the entire contents of which are incorporated herein by reference.

### BACKGROUND OF THE INVENTION

1. Field of the Invention

The present invention relates to an operation device, and more specifically, to an operation device for performing a predetermined operation with operation components provided on a front panel.

2. Description of the Related Art

Japanese Unexamined Utility Model Registration Application Publication No. 61-34141, Japanese Unexamined Utility Model Registration Application Publication No. 4-14862, and Japanese Unexamined Patent Application Publication No. 2003-107570 disclose a structure in which a switch or a controllable electric element is rotatably operated with a knob provided on a watertight panel. An operation section disclosed in these known documents has a watertight structure which is achieved by having a seal ring, such as an O ring, interposed between a shaft having a rotatably operated knob attached thereto and an opening in a casing for holding the knob. When push-button switches or the like are arranged around a rotatable operation component, the watertight structures of these push-button switches are achieved separately of that of the rotatable operation component.

### SUMMARY OF THE INVENTION

For example, FIG. 26 shows a configuration of a known operation section in an operation unit of an audio system mounted on an instrument panel of a small ship. An operation knob 1 is a rotatably operable component and is coupled to a light-guiding component 3 with a screw 2. By using a light-transparent material for a rubber ring 4 disposed at the base portion of the operation knob 1, the base portion of the operation knob 1 can be made to emit light. In this operation section, a push button 5 has an independent watertight structure, that is, the watertight structure of the push button 5 is separated from that of the operation knob 1. Therefore, it is difficult to arrange the push button 5 close to the operation knob 1.

The operation knob 1 is made watertight by inserting the operation knob 1 into an opening in a front panel 6 from above, and by hooking it with a hook of the light-guiding component 3. The watertightness is established between the rubber ring 4 having a light-guiding characteristic and the front panel 6. Therefore, it is necessary that the rubber ring 4 and the front panel 6 maintain watertight condition, that is, that the rubber ring 4 and the opening of the front panel 6 be concentric. Accordingly, a gap has to be provided between the light-guiding component 3 and a rotatable operation shaft 8 of an encoder 7 constituting a volume-control. With this known structure, it is difficult to give the encoder 7 a push function. In addition, when the operation knob 1 comes off, water penetrates into a board section, making the watertightness unreliable.

As described above, in the known watertight structure, making the operation knob 1 watertight sometimes disrupts the concentricity of the operation knob 1 and the rotatable operation shaft 8 of the encoder 7. Therefore, a gap has to be provided between the operation knob 1 and the rotatable operation shaft 8 of the encoder 7. Further, in the structure in which the operation knob 1 is hooked with the hook, two parts are subject to friction during rotation. This causes deformation due to abrasion with the passage of time or temperature changes, making the watertightness unreliable. Further, when the operation knob 1 comes off, the watertightness is hardly maintained. If a rib is provided on the bottom portion of the push button 5 adjacent to the operation knob 1 to achieve watertightness, it is difficult to make the base portion of the operation knob 1 emit light and to arrange the push button 5 close to the operation knob 1.

It is desirable to provide an operation device in which water is prevented from penetrating into the inside and in which a watertight structure of an operation knob, which is rotatably operated, and a watertight structure of a push button are linked with each other.

It is also desirable to provide a watertight operation device that allows a push button to be arranged closer to an operation knob, which is rotatably operated.

It is also desirable to provide a watertight operation device that allows for a more compact design than a known system.

It is also desirable to provide an operation device with greater design flexibility.

It is also desirable to provide an operation device having a smaller-sized, more effective watertight structure.

How to achieve such an operation device will become apparent from technical ideas and an embodiment of the present invention described below.

According to an embodiment of the present invention, there is provided an operation device including a front panel having an opening for operation, an elastically deformable operation component having an operation button and being attached to the front panel so as to cover the opening in the front panel in watertight condition, an insertion part provided in substantially a central portion of the operation component, a retaining ring attached to the insertion part in watertight condition and having a through-hole in a central portion thereof, and an operation shaft inserted through the through-hole in watertight condition. The operation button of the operation component and the operation shaft operate respective operable parts arranged inside the front panel.

According to this operation device, the watertight structure of the operation shaft having the knob is established by the elastically deformable operation component and the retaining ring. Thus, the watertight structure of the operation shaft and the watertight structure of the operation component having the operation button are linked to each other. This allows a push button to be arranged closer to the knob, which is rotatably operated. Accordingly, design flexibility is improved, and the watertight structure can be made smaller.

The operation shaft with the knob attached thereto may include a volume-adjusting operation shaft disposed on a circuit board arranged inside the front panel, and the operable part operated with the operation button of the operation component may include a switch disposed on the circuit board. Further, the retaining ring may also function as a light guide body that guides light from a light emitting element arranged on the circuit board so that at least a base portion of the knob attached to the operation shaft emits light. The operation device may further include a pressing ring attached externally to the operation component. In this case, the pressing ring applies pressure to the operation component so as to establish the watertight condition between the operation component and the front panel. Further, a display may be provided on the front panel, the display being located beside a position where the operation component is attached so that the display is arranged next to the operation component.

According to another embodiment of the present invention, there is provided an operation device for performing a predetermined operation with a knob on a front panel. An elastic component having a push button is attached to the front panel in watertight condition, the elastic component having a central portion to which a retaining ring having a through-hole is attached, the knob having an operation shaft attached thereto, the operation shaft extending through the through-hole with a seal ring interposed therebetween.

According to this operation device, the seal ring arranged in the through-hole of the retaining ring makes the operation shaft attached with the knob watertight. Further, because the retaining ring is attached to the central portion of the elastic component having the push button, the watertight structure of the elastic component having the push button and the watertight structure of the operation shaft having the knob are linked to each other. Accordingly, the elastic component having the push button can be arranged close to the operation shaft having the knob.

The elastic component may be pressed against the front panel by a pressing ring to establish the watertight condition between the elastic component and the front panel. Further, the retaining ring may include a pair of retaining rings arranged in a stacking manner at the central portion of the elastic component. A periphery of an opening in the central portion of the elastic component may be squeezed between outer peripheries of the retaining rings to establish watertight condition between the elastic component and the pair of retaining rings. Further, the seal ring interposed between the through-hole and the operation shaft may include an O ring. Further, the operation device may function as an operation section of an audio system mounted on an instrument panel in the front of a cockpit of a ship.

In a preferable embodiment of the present invention, the watertight mechanism is established by linking the watertight structure of the knob and the watertight structure of the adjoining push button. In addition, a part of the push button, which is ivory-yellow, has a light-transmitting function so that light can be emitted from the base portion of the knob. By making the knob the only component to be rotatably operated, a gap between the knob and the operation shaft of the encoder, which is rotatably operated with the knob, can be eliminated. Even when the knob comes off, watertightness can still be maintained because the knob is located outside of the watertight mechanism. In addition, the knob, whose base portion emits light, and the push button on the outer periphery of the knob can both be made watertight while arranging these components close to each other, thereby achieving greater design flexibility.

According to the above embodiment, it is possible to arrange the knob and the push button closer to each other, while preventing water from penetrating into an internal mechanism, for example, the circuit board. This allows for a more compact design than a known system, and achieves greater design flexibility. Further, this structure benefits general electronic apparatuses, because it enables to be produced smaller-sized products having a watertight structure.

### BRIEF DESCRIPTION OF THE DRAWINGS

FIG. 1 is a perspective view of a relevant part of an audio system for a small ship, showing an operation unit thereof in an open state;

FIG. 2 is a front view of the audio system;

FIG. 3 is a front view of the audio system, showing the operation unit thereof in an open state;

FIG. 4 is a side view of the audio system;

FIG. 5 is a side view of the audio system, showing the operation unit thereof in the open state;

FIG. 6 is an exploded perspective view of the operation unit;

FIG. 7 is a perspective view of a chassis;

FIG. 8 is a front view of the chassis;

FIG. 9 is a horizontal sectional view of the chassis;

FIG. 10 is a perspective view of a front cover;

FIG. 11 is a front view of the front cover;

FIG. 12 is a horizontal sectional view of the front cover;

FIG. 13 is a perspective view of a pressing ring;

FIG. 14 is a front view of the pressing ring;

FIG. 15 is a bottom view of the pressing ring;

FIG. 16 is a sectional view of the pressing ring;

FIG. 17 is a perspective view of an operation component made of rubber;

FIG. 18 is a front view of the operation component;

FIG. 19 is a bottom view of the operation component;

FIG. 20 is a horizontal sectional view of the operation component;

FIG. 21A is a perspective view of an operation knob, and FIG. 21B is a sectional view of the same;

FIG. 22A is a perspective view of an upper retaining ring, and FIG. 22B is a vertical sectional view of the same;

FIG. 23A is a perspective view of a lower retaining ring, and FIG. 23B is a vertical sectional view of the same;

FIG. 24 is an exploded perspective view showing watertight structures of the operation component and a rotatable operation shaft;

FIG. 25 is sectional view showing the watertight structures of the operation component and the rotatable operation shaft in the assembled state; and

FIG. 26 is a vertical sectional view of a relevant part showing a known watertight structure of an operation section of an audio system for a small ship.

### DESCRIPTION OF THE PREFERRED EMBODIMENTS

Now, an embodiment of the present invention will be described with reference to the drawings. The present embodiment relates to an operation section of an audio system mounted to an instrument panel that is installed in the front of a cockpit of a small ship.

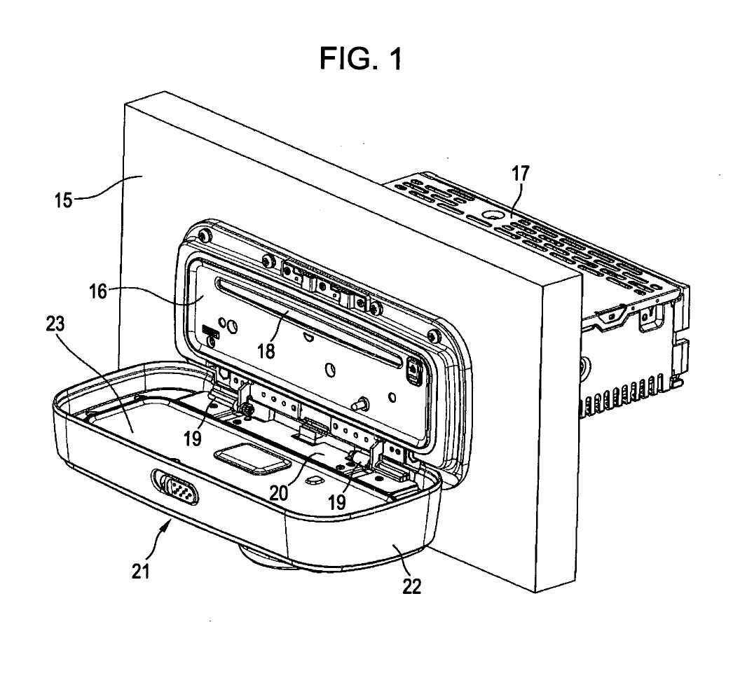

FIG. 1 shows an oblong mounting base 16 fixed on an instrument panel 15 in the front of a cockpit of a ship. A compact disc (CD) player 17 is attached behind the mounting base 16 so as to extend through the instrument panel 15 and project from the back side of the instrument panel 15. The CD player 17 has an oblong slot 18 into which a CD to be played back can be inserted. When a CD is partially inserted into the slot 18, the CD is automatically loaded into the CD player 17 where the CD is played back.

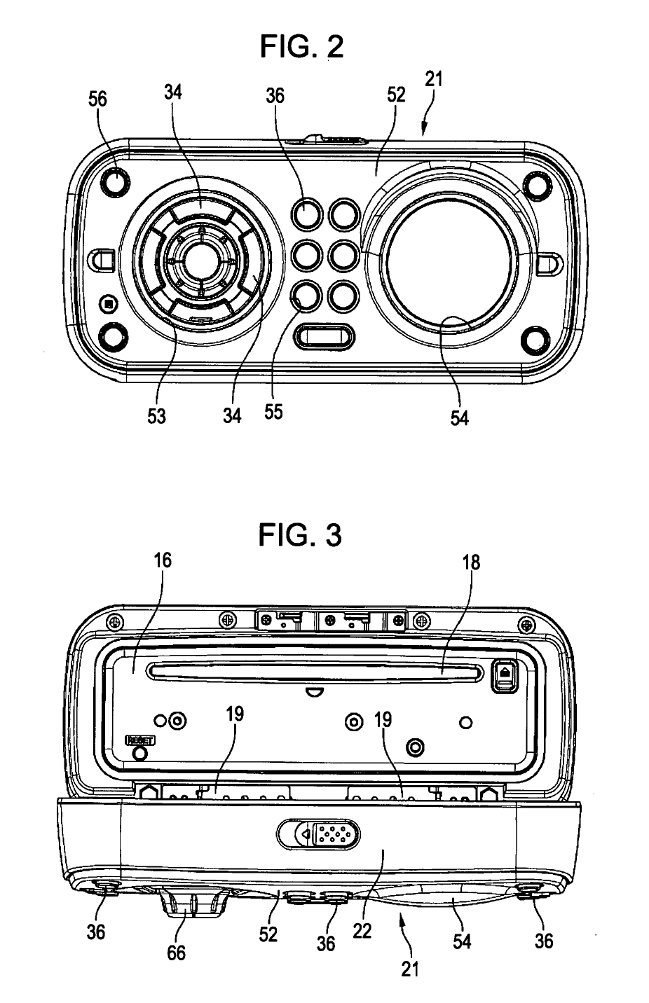

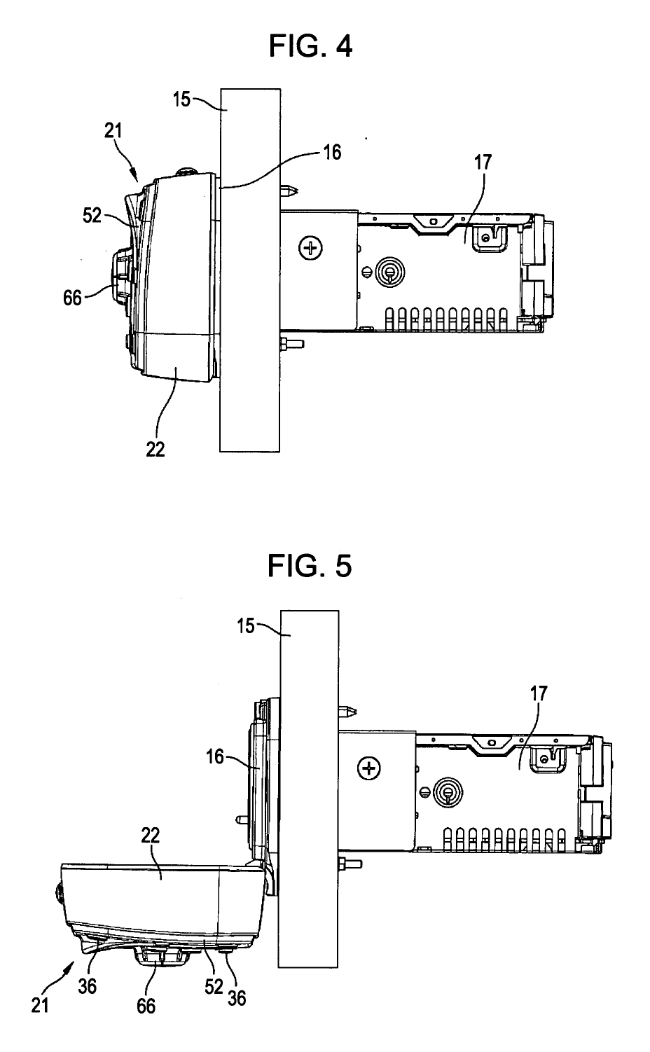

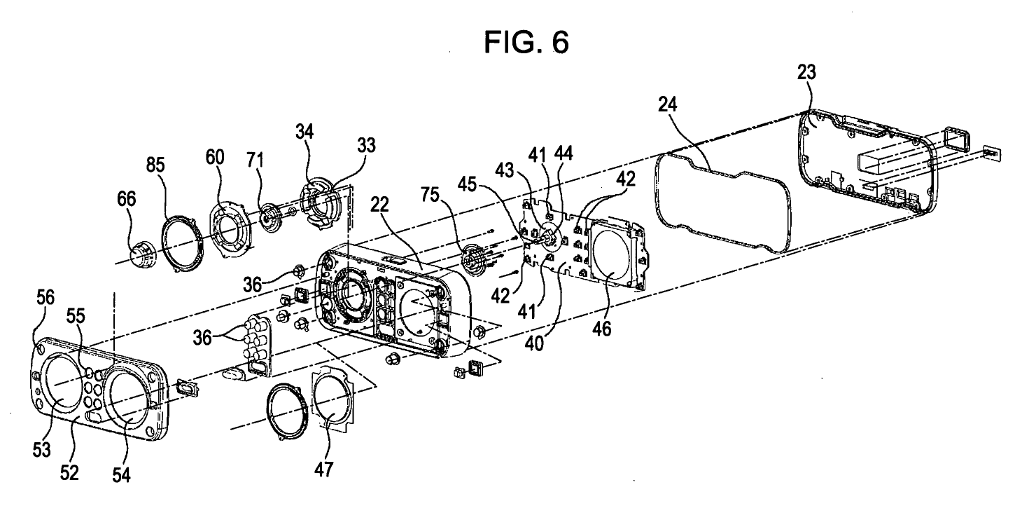

A pair of left and right hinges 19 is arranged on the lower portion of the mounting base 16. An oblong mounting plate 20 made of metal is connected to the mounting base 16 with these hinges 19. An operation unit 21 is connected to the mounting base 16 with the mounting plate 20. As shown in FIGS. 2 to 5, the operation unit 21 is supported by the hinges 19 in a rotatable fashion. FIGS. 2 and 4 show the operation unit 21 in a closed state, that is, a state in which the operation unit 21 covers the mounting base 16. FIGS. 3 and 5 show a state in which the operation unit 21 has been rotated downward on the hinges 19. In this state, the slot 18 on the mounting base 16 is exposed to allow insertion and ejection of a CD. The operation unit 21 has a chassis 22 that constitutes a front panel. Referring to FIG. 6, a cord gasket 24 is interposed between the chassis 22 and a back plate 23, thereby achieving a watertight structure between the chassis 22 and the back plate 23.

FIG. 6 is an exploded view showing each component of the operation unit 21. The chassis 22 is arranged in front of the back plate 23 with the cord gasket 24 interposed therebetween. A circuit board 40 is arranged inside the chassis 22 at a position in front of the back plate 23. A front cover 52 is attached in front of the chassis 22, thereby holding an operation component 33 and push buttons 36 onto the chassis 22.

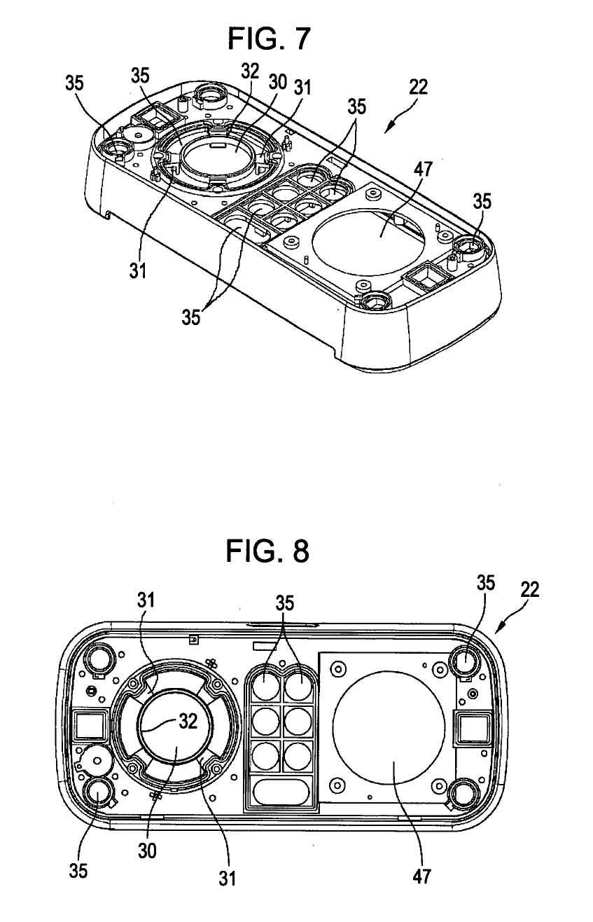

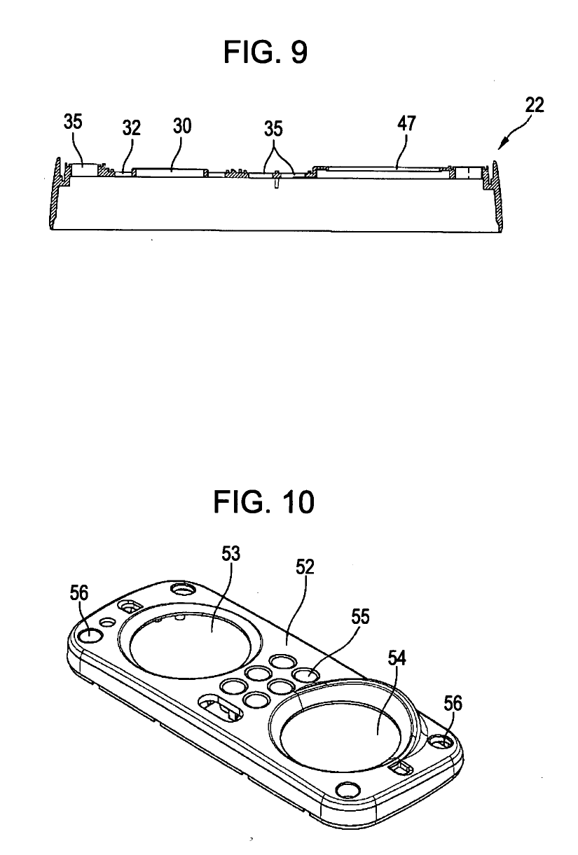

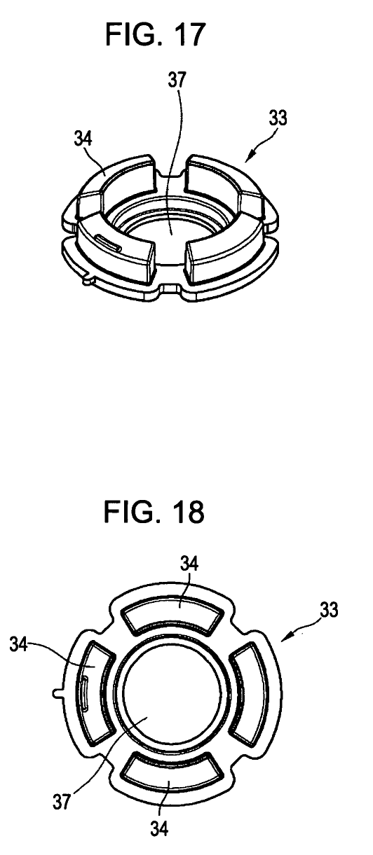

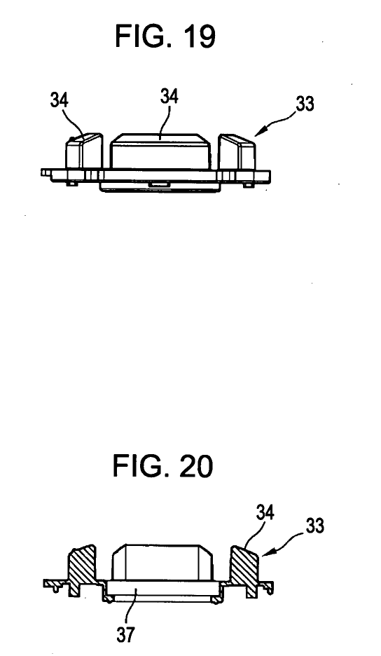

FIGS. 7 to 9 show the chassis 22 constituting the front panel. The chassis 22 has a circular opening 30 on the left side thereof. The opening 30 has four connectors 31 provided circumferentially at ninety-degree intervals. A ring connector 32, which is slightly smaller than the circular opening 30, is disposed within the opening 30 and connected to the chassis 22 with the connectors 31. The operation component 33 made of rubber is fitted into arch-shaped openings between the connectors 31. The operation component 33 is shown in FIGS. 17 to 20. The chassis 22 has openings 35 into which the push buttons 36 are fitted.

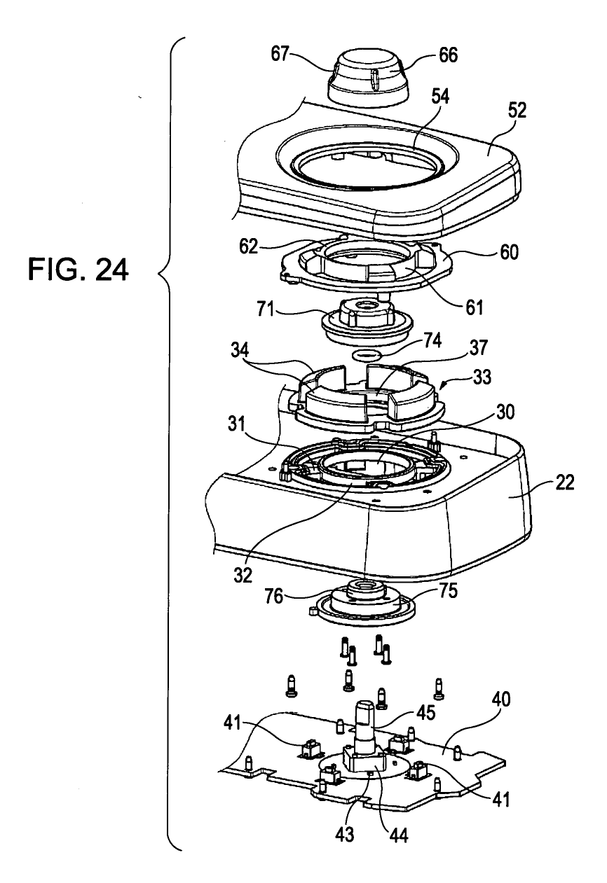

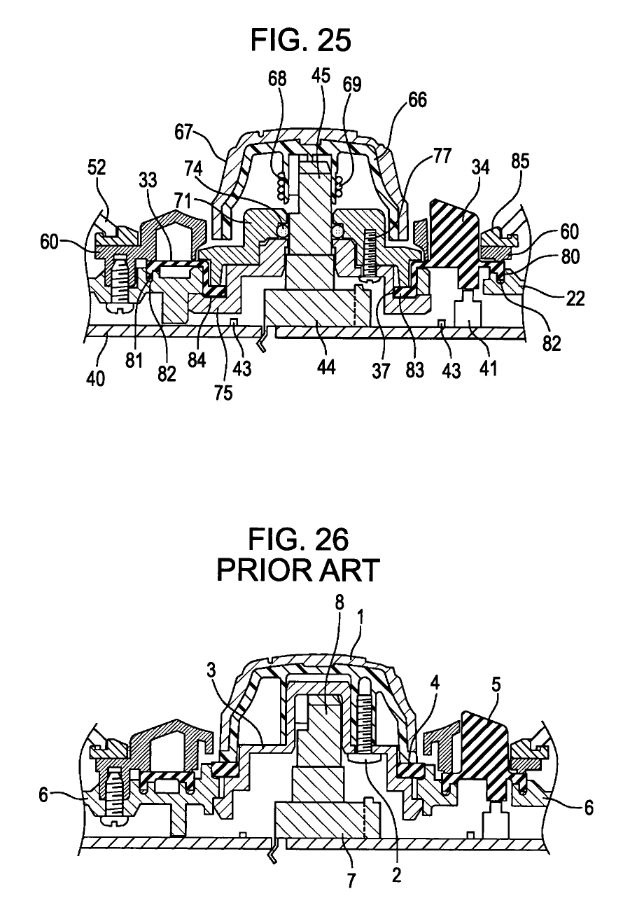

As shown in FIG. 6, the circuit board 40 accommodated within the chassis 22 has switches 41 operated with the push buttons 34 of the operation component 33, and switches 42 operated with the push buttons 36. Referring to FIGS. 24 and 25, light-emitting diodes 43 are mounted between the switches 41. An encoder 44 constituting a volume-control is mounted in an area surrounded by the switches 41 and the light-emitting diodes 43. The encoder 44 has a rotatable operation shaft 45, which is operated with an operation knob 66 to be described below. Further, as shown in FIG. 6, a liquid-crystal display panel 46 is attached to the circuit board 40 on the right side thereof. The liquid-crystal display panel 46 is viewable from the front through a transparent window 47 arranged in front thereof.

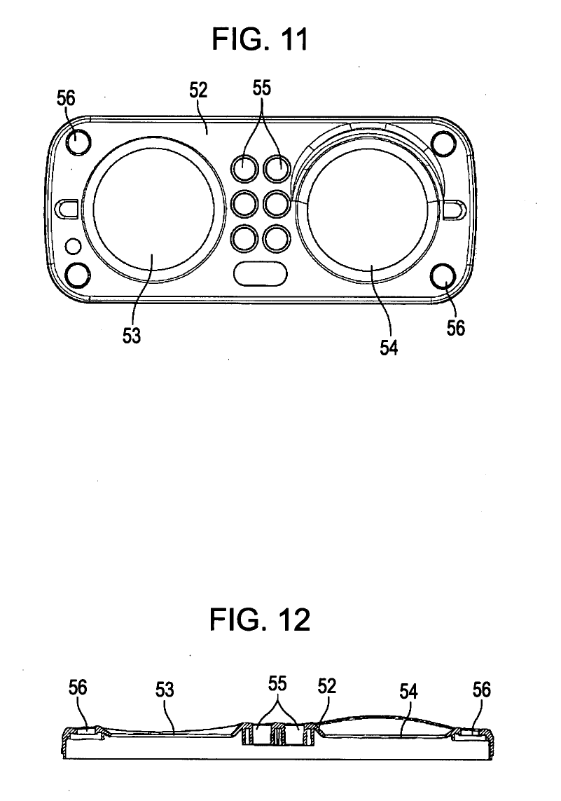

Referring to FIGS. 10 to 12, the structure of the front cover 52 arranged in front of the chassis 22 constituting the front panel will be described. The front cover 52 has a pair of left and right circular openings 53 and 54 and push-button insertion holes 55 and 56. The above-described push buttons 36 shown in FIG. 6 are fitted into these push-button insertion holes 55 and 56.

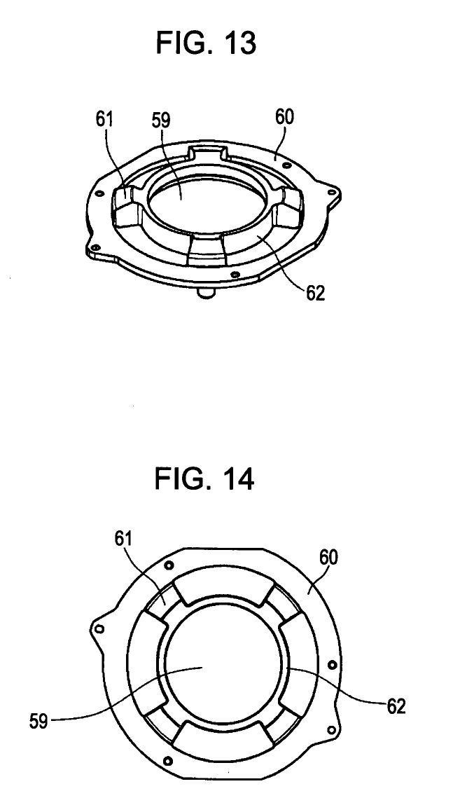

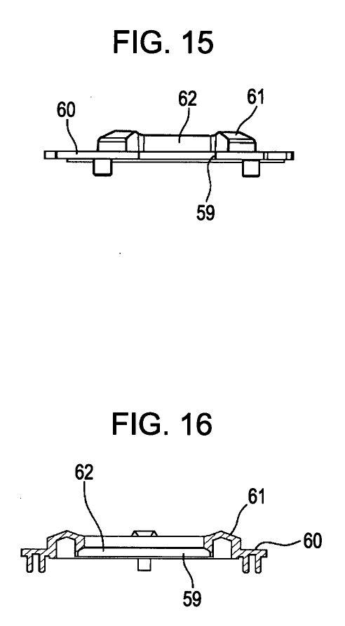

Referring to FIGS. 13 to 16, a pressing ring 60 arranged on the operation component 33 made of rubber on the chassis 22 will be described. The pressing ring 60 has a relatively large circular opening 59 in the central portion thereof, and has four connectors 61 provided circumferentially at ninety-degree intervals. Ends of the connectors 61 are connected by a ring connector 62, and the inside of the ring connector 62 forms the opening 59. The push buttons 34 of the operation component 33 are to be located on the outer periphery of the ring connector 62 and between the connectors 61. Referring to FIGS. 6 and 25, a plated decorative ring 85 is fixed on the pressing ring 60.

FIGS. 17 to 20 show the operation component 33 made of rubber. The operation component 33 is an ivory-yellow rubber body having four arch-shaped push buttons 34 along the circumference thereof. The operation component 33 has an insertion hole 37 in the central portion thereof.

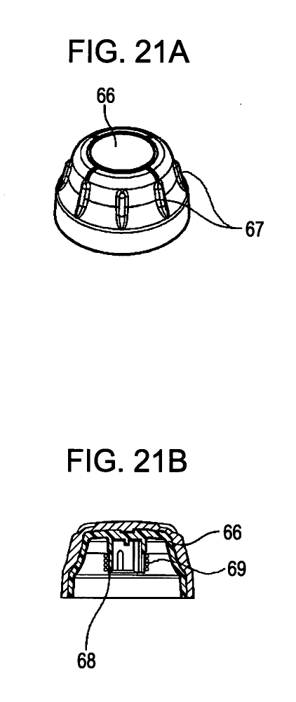

Referring to FIG. 21, an operation knob 66 will be described. The operation knob 66 is a synthetic resin body, and has a plurality of ribs 67 on the external surface thereof. These ribs 67 prevent fingers from slipping during operation. A cylindrical connector 68 is provided inside the operation knob 66. A spring 69 is wound around the cylindrical connector 68.

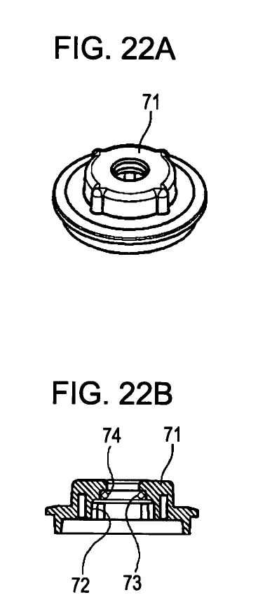

Referring to FIG. 22, an upper retaining ring 71 to be attached to the central portion of the operation component 33 made of rubber will be described. The upper retaining ring 71 has a flat, disc-like shape with a depressed portion 72 provided therein. An O ring 74 serving as a seal ring is fitted to the inner periphery of an upper shoulder 73 of the depressed portion 72.

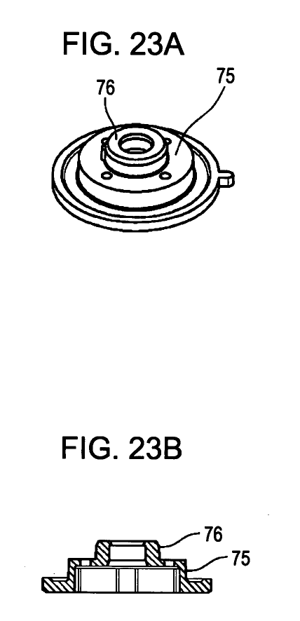

As shown in FIG. 23, a lower retaining ring 75 to be used in combination with the upper retaining ring 71 for sealing the insertion hole 37 of the operation component 33 has a projection 76 that projects upward.

FIGS. 24 and 25 show a watertight structure of the operation knob 66 for rotatably operating the rotatable operation shaft 45 of the encoder 44 on the circuit board 40, and a watertight structure of the operation component 33 having push buttons 34 arranged around the operation knob 66. In order to achieve these watertight structures, the operation component 33 is first attached so as to cover an opening 30 of the chassis 22 constituting the front panel. Then, the upper retaining ring 71 and the lower retaining ring 75 are engaged with the insertion hole 37 of the operation component 33 from above and below, respectively. These upper and lower retaining rings 71 and 75 squeeze and seal the periphery of the insertion hole 37 of the operation component 33. Then, the operation component 33 engaged with the upper and lower retaining rings 71 and 75 at the central portion thereof is pressed from above by the pressing ring 60. The rotatable operation shaft 45 of the encoder 44 on the circuit board 40 extends through the central portions of the upper and lower retaining rings 71 and 75, and is sealed by the O ring 74 fitted to the shoulder 73 of the upper retaining ring 71 so as to be made watertight. The operation knob 66 is attached to the end of the rotatable operation shaft 45 projecting from the upper retaining ring 71.

Accordingly, the watertight structure of the outer periphery of the operation component 33 is achieved by close contact between the outer periphery of the operation component 33 and the chassis 22. In this structure, the pressing ring 60 presses the outer periphery of the operation component 33 against the chassis 22. The watertight structure at the central portion of the operation component 33 having the insertion hole 37 is achieved with the upper and lower retaining rings 71 and 75. More specifically, the outer peripheries of these upper and lower retaining rings 71 and 75 squeeze the edge of the insertion hole 37 in the operation component 33 from above and below, respectively. The watertight structure of the rotatable operation shaft 45 of the encoder 44 with the operation knob 66 attached thereto is achieved with the O ring 74. The O ring 74 is fitted to the shoulder 73 of the upper retaining ring 71, among the pair of upper and lower retaining rings 71 and 75 attached to the operation component 33. Thus, the watertight structure of the rotatable operation shaft 45 of the encoder 44 is achieved with the operation component 33 made of rubber.

As shown in FIGS. 24 and 25, the operation knob 66 is fixedly fitted to the rotatable operation shaft 45 of the encoder on the circuit board 40. The push buttons 34 adjacent to the operation knob 66 are provided in the operation component 33, which is made of rubber and is elastic, and are arranged in a ring-like fashion around the operation knob 66. The operation component 33 is provided with a lip 80 having a rib 82 at the bottom side of the outer periphery of the operation component 33. The operation component 33 is also provided with a lip 83 having a rib 84 at the bottom side of the inner periphery of the operation component 33. By sandwiching these ribs, the watertight structure for preventing water from penetrating towards the side of the circuit board 40 is established. Specifically, the lip 80 on the outer periphery of the operation component 33 is fitted into a groove 81 in the chassis 22, and is squeezed between the chassis 22 and the pressing ring 60. The rib 82 is thus strongly pressed against the groove 81 in the chassis 22, whereby the watertight structure is attained. The rib 84 on the bottom side of the lip 83 provided on the inner periphery of the operation component 33 is squeezed between the outer peripheries of the upper and lower retaining rings 71 and 75, and is pressed against the upper surface of the outer periphery of the lower retaining ring 75. The chassis 22 and the pressing ring 60 are fastened together with screws. The upper and lower retaining rings 71 and 75 are coupled together with screws 77. The pressing ring 60 and the front cover 52 can be integrated into a single component if the decorative ring 85 is not necessary.

The rotatable operation shaft 45 of the encoder 44 is made watertight by the O ring 74 sandwiched between the upper and lower retaining rings 71 and 75. This structure can allow the encoder 44 to have a push function. Further, in this watertight structure, the upper and lower retaining rings 71 and 75 and the push buttons 34 of the operation component 33 are made of a light-transparent material. The use of the light-transparent material can allow the base portion of the operation knob 66 to emit light by guiding light from the light-emitting diodes 43 on the circuit board 40. In addition, even when the operation knob 66 comes off, the watertightness can still be maintained because the operation knob 66 is located outside of the watertight mechanism. This structure allows for a reduced distance between the operation knob 66 and the push buttons 34, and greater design flexibility.

According to the structure of the present embodiment shown in FIGS. 24 and 25, the operation knob 66 and the push buttons 34 can be arranged closer to each other, while preventing water from penetrating into the circuit board 40. This allows for a more compact design than a known system, as well as achieving greater design flexibility. Further, this structure benefits general electronic apparatuses, because it enables to be produced smaller-sized products having a watertight structure.

Next, an overall operation of the audio system including the CD player 17 having the operation unit 21 with the aforementioned watertight structure will be described. As shown in FIGS. 1, 3, and 5, the operation unit 21 is rotated downward on the hinges 19. Then, a CD is inserted into the CD player 17 through the slot 18 provided on the mounting base 16, and the CD is played back with the CD player 17. When playback is to be performed, the operation unit 21 is rotated upward about the hinges 19 so as to be returned to the original state as shown in FIGS. 2 and 4. Sound volume, for example, may be adjusted by rotatably operating the operation knob 66 attached to the rotatable operation shaft 45. Other predetermined operations can be performed by pressing push buttons 36 exposed through the push-button insertion holes 55 in the front cover 52, namely, by operating the switches 42 on the circuit board 40.

After the playback, the operation unit 21 is rotated downward again as shown in FIGS. 1, 3, and 5, and the CD is ejected from the slot 18 on the mounting base 16. Another CD may be inserted through the slot 18 and played back, if desired.

The embodiment of the present invention has been described referring to the drawings. However, it should be understood by those skilled in the art that various modifications, combinations, sub-combinations, and alterations may occur depending on design requirements and other factors insofar as they are within the scope of the appended claims or the equivalents thereof. For example, the specific shape, the design, or the like of the operation unit 21 according to the above embodiment can be variously modified. The present invention can be broadly applied to any operation section in which watertightness is important.

What is claimed is:

1. An operation device comprising:
a front panel having an opening for operation;
an elastically deformable operation component having an operation button and being attached to the front panel so as to cover the opening in the front panel in watertight condition;
an insertion part provided in substantially a central portion of the operation component;
a retaining ring attached to the insertion part in watertight condition and having a through-hole in a central portion thereof; and
an operation shaft having a knob attached thereto and extending through the through-hole in watertight condition,
wherein the operation button of the operation component and the operation shaft operate respective operable parts arranged inside the front panel.

2. The operation device according to claim 1, wherein the operation shaft with the knob attached thereto includes a volume-adjusting operation shaft disposed on a circuit board arranged inside the front panel, and the operable part operated with the operation button of the operation component includes a switch disposed on the circuit board.

3. The operation device according to claim 2, wherein the retaining ring also functions as a light guide body that guides light from a light emitting element arranged on the circuit board so that the light is emitted from at least a base portion of the knob attached to the operation shaft.

4. The operation device according to claim 1, further comprising a pressing ring attached externally to the operation component, wherein the pressing ring applies pressure to the operation component so as to establish the watertight condition between the operation component and the front panel.

5. The operation device according to claim 1, wherein a display is provided on the front panel, the display being located beside a position where the operation component is attached so that the display is arranged next to the operation component.

6. An operation device for performing a predetermined operation with a knob on a front panel,
wherein an elastic component having a push button is attached to the front panel in watertight condition, the elastic component having a central portion to which a retaining ring having a through-hole is attached, the knob having an operation shaft attached thereto, the operation shaft extending through the through-hole with a seal ring interposed therebetween.

7. The operation device according to claim 6, wherein the elastic component is pressed against the front panel by a pressing ring to establish the watertight condition between the elastic component and the front panel.

8. The operation device according to claim 6, wherein the retaining ring includes a pair of retaining rings arranged in a stacking manner at the central portion of the elastic component, and wherein a periphery of an opening in the central portion of the elastic component is squeezed between outer peripheries of the retaining rings to establish watertight condition between the elastic component and the pair of retaining rings.

9. The operation device according to claim 6, wherein the seal ring interposed between the through-hole and the operation shaft includes an O ring.

10. The operation device according to claim 6, wherein the operation device functions as an operation section of an audio system mounted on an instrument panel in the front of a cockpit of a ship.
